(19) United States
(12) Patent Application Publication
(10) Pub. No.: US 2009/0001446 A1
(43) Pub. Date: Jan. 1, 2009

(54) FLASH MEMORY DEVICE AND METHODS FOR FABRICATING THE SAME

(75) Inventor: Sung Jin Kim, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/147,392

(22) Filed: Jun. 26, 2008

(30) Foreign Application Priority Data
Jun. 27, 2007 (KR) 10-2007-0063756

(51) Int. Cl. H01L 29/788; H01L 21/336

(52) U.S. Cl. 257/316; 438/265; 257/E29.302; 257/E21.422; 257/E21.433

(57) ABSTRACT

A method of fabricating a flash memory device includes forming a stack electrode on a semiconductor substrate; forming a side spacer on a side wall of the stack electrode; forming a photo-resist film pattern with a predetermined thickness on the side wall of the side spacer; and forming a source/drain junction on the semiconductor substrate through ion implant using the photo-resist film as a mask for ion implant.

### CROSS-REFERENCE TO RELATED APPLICATION

This application claims priority to Korean Application No. 10-2007-0063756, filed on Jun. 27, 2007, which is incorporated herein by reference in its entirety.

### BACKGROUND

1. Field of the Invention

Embodiments of the present invention relate to a flash memory device and methods for making the same. More particularly, embodiments of the present invention relate to methods of fabricating a flash memory device so as to mitigate the risk of an electron trap phenomenon between a side spacer and a floating gate, thus improving product reliability.

2. Background of the Invention

In general, a flash memory device is a type of Programmable Read Only Memory (PROM) that can overwrite electrical data. Another type of PROM is Erasable PROM (EPROM). In an EPROM device a group of memory cells are erased by ultraviolet rays but memory cells thereof have a small area, consisting of one transistor. Electrically Erasable PROM (EEPROM) devices can be electrically erased, but cell area consists of two transistors and is therefore larger. A flash EEPROM device combines features of both types of PROM. A flash EEPROM device performs both a program inputting function of an Erasable PROM (EPROM) device, an erasing function of an EEPROM, and has a memory cell size of one transistor.

A flash memory device is called a non-volatile memory device because information stored in memory is not erased even if power is turned off. Flash memory devices may be classified according to cell array structure. For example, in a NOR type structure cells are disposed in parallel between a bit line and ground, and in a NAND type structure cells are disposed in series between the bit line and ground.

Further, flash memory devices may be classified according to a unit cell structure, e.g., including a stack gate type flash memory device and a split gate type flash memory device. Flash memory devices may also be classified according to a form of an electric charge storage layer thereof, e.g., including a floating gate device and a Silicon-Oxide-Nitride-Oxide-Silicon (SONOS) device.

FIG. 1 is a cross-sectional view of a common stack gate type flash memory device of a related art.

In the stack gate type flash memory device, a multi-layered structure of stack electrode 110 is formed in which a gate oxide film 112, a floating gate 114, an interlayer insulating film 116, and a control gate 118 are sequentially stacked on an active area of a semiconductor substrate 100. A source junction 130 and a drain junction 140 are then formed by doping impurities within lateral regions of semiconductor substrate 100 such that a channel area below the stack electrode 110 is formed between the lateral regions.

A side spacer 120 may be formed of an insulating film material on a side wall of the stack electrode 110. The side spacer 120 may be used as a mask when forming the source junction 130 and the drain junction 140 through ion implantation.

Further, in order to reduce contact resistance and surface resistance, a salicide film 150 made of a material having low resistivity may be formed above the control gate 118, the source junction 130, and the drain junction 140. The salicide film 150 may be made of a compound consisting of a metal, such as titanium (Ti) cobalt (Co), tungsten (W), and nickel (Ni), and silicone.

The gate oxide film 112 may be referred to as a tunnel oxide film and may be formed with a silicone oxide film in which a silicone layer of the semiconductor substrate 100 is thermally oxidized or a silicone oxynitride film in which a silicone oxide film is nitrified.

The floating gate 114 may be made of conductive poly silicone or polycide and performs a function of a storage node having an electric charge.

The interlayer insulating film 116 may be formed with a dielectric film having an oxide-nitride-oxide (ONO) structure and performs a function of insulating the floating gate 114 and the control gate 118 from each other.

The control gate 118 may be made of conductive poly silicone or polycide and performs a function of adjusting a current flow between the source junction 130 and the drain junction 140.

The side spacer 120 may be positioned on a side wall of the stack electrode 110 to intercept impurities introduced by ion implantation during formation of the source junction 130 and the drain junction 140. The side spacer 120 thereby prevents a short channel effect by extending a channel width between the source junction 130 and the drain junction 140. The side spacer 120 may be made of a silicon oxide film and a silicone nitride film, which are insulating films. Specifically, the side spacer 120 may be made of an oxidation layer 122, a High Temperature Oxide (HTO) film and/or a Tetra Ethyl Ortho Silicate (TEOS) film 124, and a nitride film 126.

A method of fabricating a stack gate type flash memory device having the above-described structure is described with reference to FIGS. 2A to 2G.

First, as shown in FIG. 2A, after a gate oxide film 112′ is thinly formed on an entire surface of the semiconductor substrate 100 through a thermal oxidation process, a floating gate film 114′, an interlayer insulating film 116′, and a control gate film 118′ are sequentially deposited over the gate oxide film 112′.

Next, as shown in FIG. 2B, a photo-resist film (PR) pattern (PR-1) is formed over the control gate film 118′ through a photo-lithography process so as to close only an area in which the stack electrode 110 is to be formed. An exposed part of the semiconductor layers 112′, 114′, 116′, and 118′ are then removed, using the corresponding photo-resist film pattern (PR-1) as a mask for etching.

The photo-lithography process includes a series process of coating, exposing, and developing a photo-resist film. The etching process may include dry etching having anisotropy etching characteristics. After the stack electrode 110 is completed the used photo-resist film pattern (PR-1) may be removed through an ashing process, etc.

Next, as shown in FIG. 2C, in order to form the side spacer 120, an oxidation layer 122′ is formed on an entire surface of the semiconductor substrate 100 in which the stack electrode 110 is formed through a thermal oxidation process. An HTO film 124′ and a nitride film 126′ are then sequentially deposited.

The oxidation layer 122′ is thinly formed, e.g., with a thickness of about 40 to 60 Å, the HTO film 124′ is thinly formed, e.g., with a thickness of about 75 Å, and the nitride film 126′ is formed relatively thickly, e.g., with a thickness of about 700 to 1500 Å.

Instead of or in addition to the HTO film 124′, a TEOS film may be used. In addition, a silicone nitride film such as SiN or Si₃N₄ may be used as the nitride film 126′.

Thereafter, as shown in FIG. 2D, a surface of the control gate 118 of the stack electrode 110 is exposed by performing dry etching with anisotropy etching characteristics to remove upper portions of the nitride film 126′, the HTO film 124′, and the oxidation layer 122′, thus forming the side spacer 120 on a side wall side of the stack electrode 110.

Thereafter, as shown in FIG. 2E, the source junction 130 and the drain junction 140 are formed using the stack electrode 110 and the side spacer 120 as a mask for an ion implant process to implant impurities around the stack electrode 110. Thus, the source junction 130 and the drain junction 140 are formed on exposed surfaces of the semiconductor substrate 100.

After ion implantation, a heat treatment process such as Rapid Thermal Processing (RTP) for activating the implanted impurities is performed.

Next, as shown in FIG. 2F, in order to form the salicide film 150, an oxide film pattern OL for suppressing salicide is formed to expose only the stack electrode 110, the source junction 130, and the drain junction 140. Specifically, an oxide film for suppressing salicide may be deposited over an entire surface of the structures formed thus far and a photo-resist film pattern may be formed over the deposited oxide film through a photo-lithography process. Exposed portions of the deposited oxide film may then be selectively etched away using the corresponding photo-resist film pattern as a mask. After the oxide film pattern OL for suppressing salicide is formed to close only a non-salicide area, the used photo-resist film pattern may be removed.

Thereafter, as shown in FIG. 2G, the salicide film 150 is formed on the exposed stack electrode 110, source junction 130, and drain junction 140 using the oxide film pattern OL to suppress salicide elsewhere. Specifically, a metal film for forming salicide is deposited in a portion exposed by the oxide film pattern OL. Next, by performing a heat treatment process, the metal film becomes salicide by reacting with poly silicone of the control gate 118 and silicone of the source junction 130 and the drain junction 140. Once the salicide film 150 is formed the used oxide film pattern OL for suppressing salicide is removed through a wet strip process using a phosphoric acid (H₃PO₄) solution. Thereby, a process of fabricating a stack gate type flash memory device is completed.

However, the conventional method of fabricating a stack gate type flash memory device has the following problems.

The side spacer 120 consists of a combination of oxide films 122 and 124, each having a relatively small thickness, and the nitride film 126, having a large thickness relative to the oxide films 122 and 124. If the thick nitride film 126 for intercepting ion implanted impurities is formed directly adjacent to the side wall of the stack electrode 110, a looseness phenomenon occurs due to poor adhesion. To prevent the looseness phenomenon, the thin oxide films 122 and 124 are interposed therebetween. A combination of the oxidation layer 122 and the HTO film (and/or a TEOS film) 124 are used as the interposed oxide films because they provide excellent electrical characteristics in the final structure.

However, formation of the thick nitride film 126 causes structural stress at the interface between the thick nitride film 126 and the thin oxide films 122 and 124. The crystal lattice structures of the side spacer films 122, 124, and 126 become unstable around the interface of the oxide films 122 and 124 with the thick nitride film 126. As a result, an electron trap phenomenon of a charge gain or charge loss to the floating gate 114 occurs, thereby deteriorating reliability of the flash memory product.

### SUMMARY OF SOME EXAMPLE EMBODIMENTS

In general, example embodiments of the invention relate to a flash memory device and methods for fabricating the same such that an electron trap phenomenon is mitigated. The exemplary methods include forming a source/drain junction using a photo-resist film pattern instead of a thick nitride film for a spacer, thus improving product reliability.

A first embodiment of a method of fabricating a flash memory device includes: forming a stack electrode having a stacking structure including a gate oxide film, a floating gate, an interlayer insulating film, and a control gate on a semiconductor substrate; forming a side spacer on a side wall of the stack electrode; forming a photo-resist film pattern with a predetermined thickness on a side wall of the side spacer; and forming a source/drain junction on the semiconductor substrate through ion implant using the photo-resist film as a mask for ion implant.

According to a second embodiment, there is provided a flash memory device, including: a stack electrode having a stacking structure including a gate oxide film, a floating gate, an interlayer insulating film, and a control gate formed on a semiconductor substrate; a side spacer formed on a side wall of the stack electrode; and a source/drain junction formed on the semiconductor substrate.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments given in conjunction with the accompanying drawings, in which:

FIG. 1 is a cross-sectional view of a flash memory device of a related art;

FIGS. 2A to 2G are cross-sectional views sequentially illustrating processes of a method of fabricating a prior art flash memory device; and

FIGS. 3A to 3H are cross-sectional views sequentially illustrating processes of a method of fabricating a flash memory device according to an embodiment of the present invention.

### DETAILED DESCRIPTION OF SOME EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

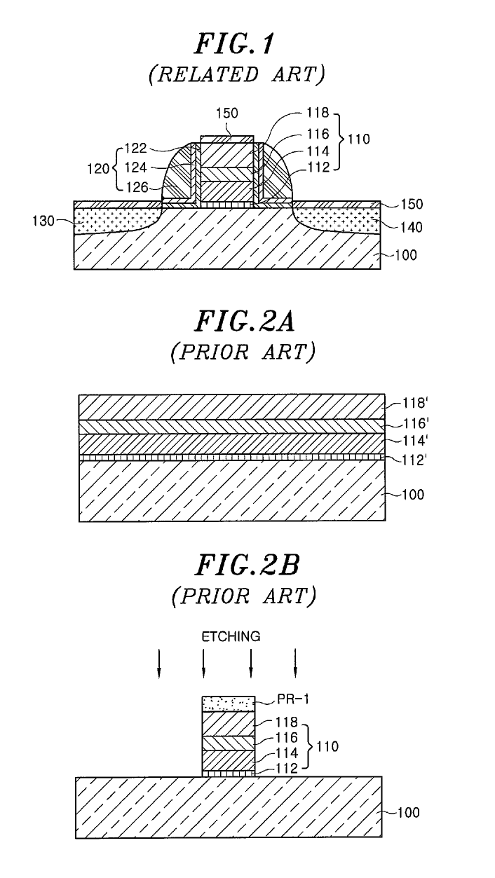

As described above with reference to FIG. 1, a stack gate type flash memory device may include a stack electrode 110 that is formed in a multi-layered structure including a gate oxide film 112, a floating gate 114, an interlayer insulating film 116, and a control gate 118 on an active area of a semiconductor substrate 100. The structure may also include a side spacer 120 formed on a side wall of the stack electrode 110 to extend a channel length, as well as a source junction 130 and a drain junction 140 formed on the semiconductor substrate 100 with the stack electrode 110 interposed therebetween.

The side spacer 120 intercepts impurities over a wide region around the stack electrode 110 that would otherwise be implanted in the semiconductor substrate 100 by ion implantation when forming the source junction 130 and the drain junction 140. The side spacer 120 may be formed with a solid insulating film comprising a combination of an oxide film and a nitride film. Specifically, the side spacer 120 may be sequentially formed with an oxidation layer 122, a HTO film and/or a TEOS film 124, and a nitride film 126 on a side wall of the stack electrode 110. The oxidation layer 122 and the HTO film 124 may be formed with a thickness of 100 Å or less. The nitride film 126 may be formed with a thickness of 700 to 1500 Å.

However, use of the thick nitride film 126 in the spacer generates stress at the interface with the thinner films 122 and 124. As a result an electron trap phenomenon occurs due to instability of an internal crystal lattice, thereby deteriorating product reliability.

Therefore, in order to prevent or mitigate such an electron trap phenomenon, a photo-resist film pattern may be used instead of the thick nitride film 126 to intercept implantation of impurities around the stack electrode 110 during formation of the source junction 130 and the drain junction 140.

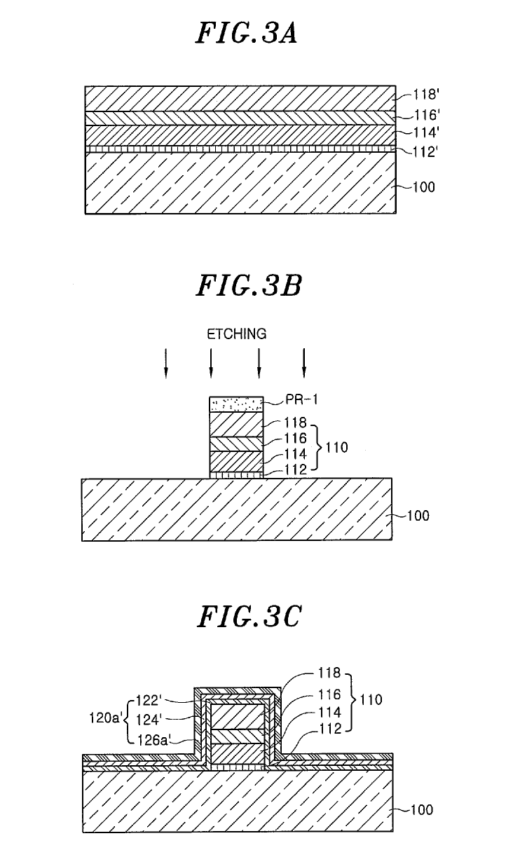

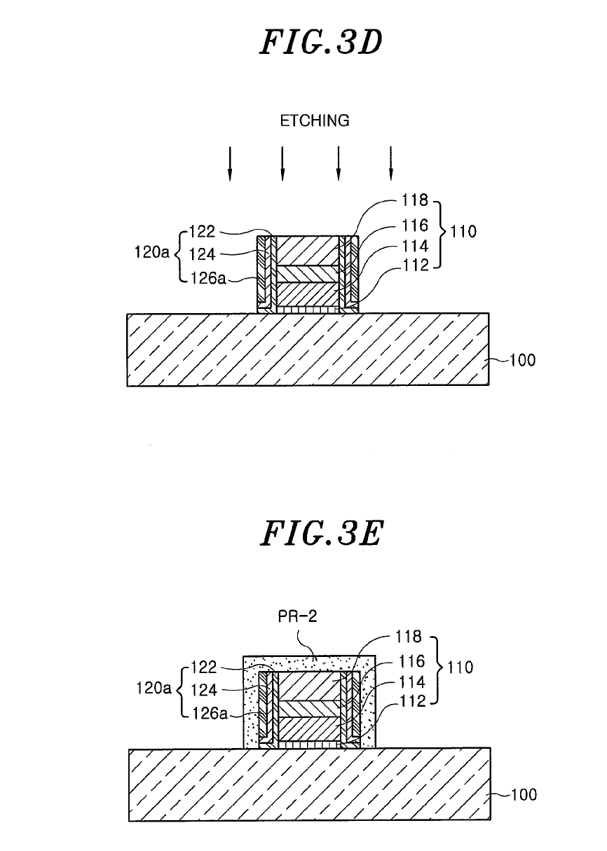

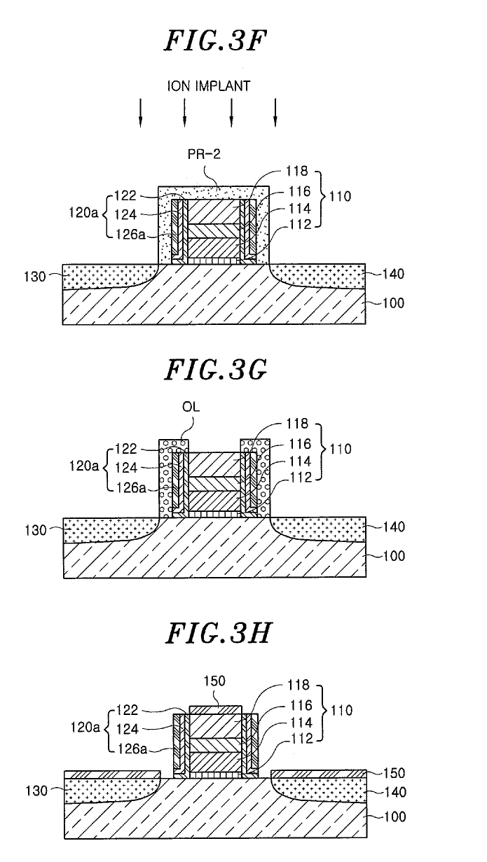

FIGS. 3A to 3H are cross-sectional views sequentially illustrating processes of an exemplary method of fabricating a flash memory device using a photo-resist film pattern as a spacer.

First, as shown in FIG. 3A, a gate oxide film 112′ may be thinly formed on an entire surface of the semiconductor substrate 100 through a thermal oxidation process, and a floating gate layer 114′, an interlayer insulating film 116′, and a control gate film 118′ may be sequentially deposited over the gate oxide film 112′.

The gate oxide film 112′ may be formed with a silicone oxide film or a silicone oxynitride film, the floating gate layer 114′ and the control gate layer 118′ may be made of poly silicone or polycide, and the interlayer insulating film 116′ may be formed with a dielectric film of an ONO structure.

Next, as shown in FIG. 3B, in order to close only an area in which the stack electrode 110 is to be formed, the photo-resist film pattern (PR-1) is formed over the control gate film 118′ through a photo-lithography process. An exposed portion of the semiconductor layers 112′, 114′, 116′, and 118′ may then be removed through dry etching using the photo-resist film pattern (PR-1) as a mask for etching. Then the used photo-resist film pattern (PR-1) is removed.

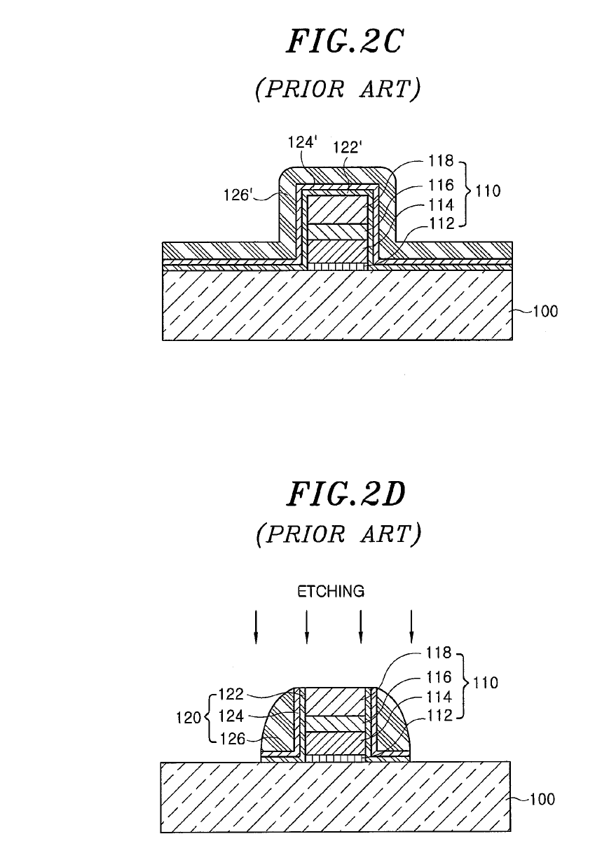

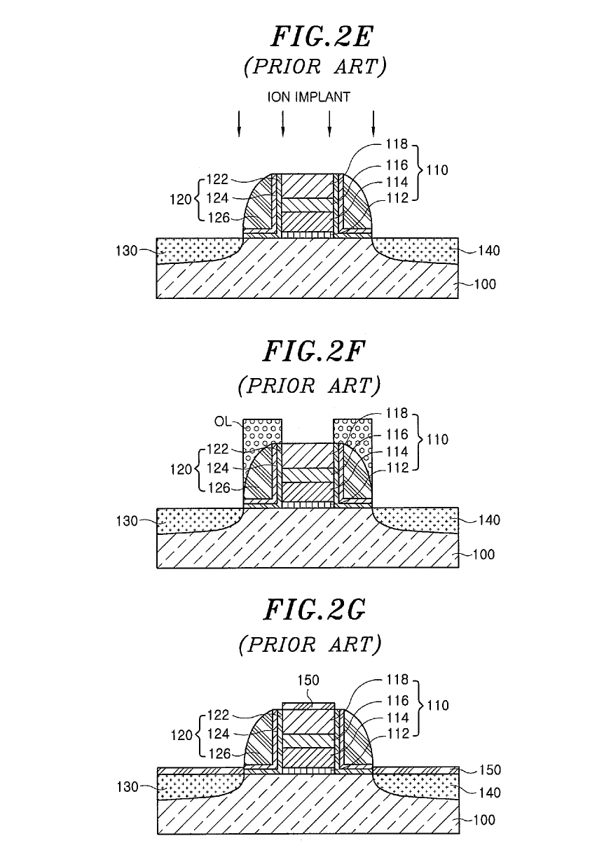

Next, as shown in FIG. 3C, in order to form the side spacer 120a, a thin oxidation layer 122′ may be formed (e.g., having a thickness of 80 to 100 Å) through a thermal oxidation process on an entire surface of the semiconductor substrate 100 on which the stack electrode 110 is formed. An HTO film 124′, having a thickness of 150 to 200 Å, and a nitride film 126a′, having a thickness of 100 to 200 Å, preferably 150 to 200 Å, may then be sequentially deposited. In contrast, the nitride film 126a′ is conventionally formed more thickly, e.g., with a thickness of about 700 to 1500 Å (see FIG. 2C).

Instead of or in addition to the HTO film 124′, a TEOS film having a thickness of 150 to 200 Å may be used. In addition a silicone nitride film such as SiN or Si₃N₄ may be used as the nitride film 126a′.

Thereafter, as shown in FIG. 3D, the side spacer 120a is formed on the side wall side of the stack electrode 110 by entirely removing upper portions of the nitride film 126a′, the HTO film 124′, and the oxidation layer 122′ until a surface of the control gate 118 is exposed. The upper portions of the nitride and oxide films 122′, 124′, and 126a′ may be removed by performing, e.g., dry etching having anisotropy etching characteristics.

Thereafter, as shown in FIG. 3E, in order to compensate for a reduced thickness of the nitride film 126′ for the spacer, as compared with a conventional nitride film thickness, a second photo-resist film pattern (PR-2) may be formed having a thickness of 500 to 1400 Å on the side wall of the nitride film 126a′. The second photo-resist film pattern (PR-2) may be formed through a photo-lithography process such that the combined thickness of the second photo-resist film pattern (PR-2) and the nitride film 126a′ is substantially equal to a thickness of a conventionally formed nitride film 126a′.

Thereafter, as shown in FIG. 3F, the source junction 130 and the drain junction 140 may be formed using the second photo-resist film pattern (PR-2) as a mask for an ion implant process to implant impurities around the stack electrode 110. Thus, the source junction 130 and the drain junction 140 are formed on exposed surfaces of the semiconductor substrate 100.

Thereafter, the used second photo-resist film pattern (PR-2) may be removed and a heat treatment process for activating implanted impurities may be performed.

Thereafter, as shown in FIG. 3G, in order to form a salicide film 150, an oxide film pattern OL for suppressing salicide may be formed to expose only the stack electrode 110, the source junction 130, and the drain junction 140. Specifically, after depositing the oxide film for suppressing salicide over an entire surface of the structures formed thus far, a photo-resist film pattern may be formed over the deposited oxide film through a photo-lithography process. Exposed portions of the deposited oxide film may then be selectively etched away using the photo-resist film pattern as a mask. After the oxide film pattern OL for suppressing salicide is formed to close only a non-salicide area, the used photo-resist film pattern may be removed.

Thereafter, as shown in FIG. 3H, the salicide film 150 may be formed on the stack electrode 110, the source junction 130, and the drain junction 140 exposed by the oxide film pattern OL for suppressing salicide. Specifically, a metal film for forming salicide becomes salicide by reacting with poly silicone of the control gate 118 and silicone of the source junction 130 and the drain junction 140 during a heat treatment process performed after depositing the metal film on exposed portions. Once the salicide film 150 is formed the used oxide film pattern OL for suppressing salicide may be removed through a wet strip using a phosphoric acid solution.

Thereby, a process of fabricating a stack gate type flash memory device is completed.

By using a photo-resist film pattern (PR-2) instead of a thick nitride film for the spacer when forming the source junction 130 and the drain junction 140, an electron trap phenomenon can be prevented or mitigated.

Therefore, after the oxidation layer 122′ and the HTO film 124′ are formed, the second photo-resist film pattern (PR-2) may be immediately formed. However, according to the above process, because the HTO film 124′ and the oxidation layer 122′ are oxide films, they are subject to being removed by the phosphoric acid applied by the wet strip process used to remove the salicide suppressing oxide film pattern OL. Without the HTO film 124′ and the oxidation layer 122′ the stack electrode 110 may be damaged. In order to prevent deterioration of the HTO film 124′ and the oxidation layer 122′ and any consequent damage of the stack electrode 110, a relatively thin nitride film 126a′ may be formed on an outside surface of the HTO film 124′.

As described above, an electron trap phenomenon between a side spacer and a floating gate can be prevented or mitigated by forming a thin nitride film 126a. By preventing or mitigating the electron trap phenomenon, product stability and reliability can be improved.

While the invention has been shown and described with respect to the preferred embodiments, it will be understood by those skilled in the art that various changes and modifications may be made without departing from the spirit and scope of the invention as defined in the following claims.

What is claimed is:

1. A method of fabricating a flash memory device, comprising:
forming a stack electrode having a stacking structure including a gate oxide film, a floating gate, an interlayer insulating film, and a control gate on a semiconductor substrate;
forming a side spacer on a side wall of the stack electrode;
forming a photo-resist film pattern with a predetermined thickness on a side wall of the side spacer; and
forming a source/drain junction on the semiconductor substrate through ion implant using the photo-resist film as a mask for ion implant.

2. The method of claim 1, wherein forming a side spacer comprises:
forming sequentially an oxidation layer, a High Temperature Oxide (HTO) film and a nitride film on the side wall of the stack electrode.

3. The method of claim 1, wherein forming a side spacer comprises:
forming sequentially an oxidation layer, a Tetra Ethyl Ortho Silicate (TEOS) film and a nitride film on the side wall of the stack electrode.

4. The method of claim 1, further comprising:
forming a salicide film on the stack electrode and the source/drain junction after forming the source/drain junction.

5. The method of claim 1, wherein the photo-resist film pattern is formed with a thickness of about 500 to 1400 Å on the side wall of the side spacer.

6. The method of claim 2, wherein the nitride film is formed with a thickness of 100 to 200 Å.

7. The method of claim 3, wherein the nitride film is formed with a thickness of 100 to 200 Å.

8. A flash memory device, comprising:
a stack electrode having a stacking structure including a gate oxide film, a floating gate, an interlayer insulating film, and a control gate formed on a semiconductor substrate;
a side spacer formed on a side wall of the stack electrode; and
a source/drain junction formed on the semiconductor substrate.

9. The device of claim 8, further comprising:
a salicide film formed on the stack electrode and the source/drain junction.

10. The device of claim 8, wherein the side spacer comprises:
an oxidation layer, a High Temperature Oxide (HTO) film and a nitride film sequentially formed on the side wall of the stack electrode.

11. The device of claim 8, wherein the side spacer comprises:
an oxidation layer, a Tetra Ethyl Ortho Silicate (TEOS) film and a nitride film sequentially formed on the side wall of the stack electrode.

12. The device of claim 10, wherein the oxidation layer is formed with a thickness of 80 to 100 Å.

13. The device of claim 10, wherein the HTO film is formed with a thickness of 150 to 200 Å.

14. The device of claim 10, wherein the nitride film is formed with a thickness of 100 to 200 Å.

15. The device of claim 11, wherein the oxidation layer is formed with a thickness of 80 to 100 Å.

16. The device of claim 11, wherein the TEOS film is formed with a thickness of 150 to 200 Å.

17. The device of claim 11, wherein the nitride film is formed with a thickness of 100 to 200 Å.
